(19) United States
(12) Patent Application Publication
(10) Pub. No.: US 2026/0305129 A1
(43) Pub. Date: Oct. 1, 2026

(54) DISPLAY DEVICE AND ELECTRONIC DEVICE COMPRISING THE SAME

(71) Applicant: Samsung Display Co., Ltd., Yongin-si (KR)

(72) Inventors: Hidekazu HAYASHI, Yongin-si (KR); Younjoeng GOH, Yongin-si (KR); Ja Hun KOO, Yongin-si (KR); Kicheol SONG, Yongin-si (KR); Taek-Sun SHIN, Yongin-si (KR)

(73) Assignee: Samsung Display Co., Ltd., Yongin-si (KR)

(21) Appl. No.: 19/398,258

(22) Filed: Nov. 24, 2025

(30) Foreign Application Priority Data
Apr. 1, 2025 (KR) 10-2025-0042136

(51) Int. Cl. H10K 59/80; H10K 102/00

(52) U.S. Cl. CPC H10K 59/8722; H10K 59/8794; H10K 2102/351

(57) ABSTRACT

A display device includes a display panel, a sealing layer on a side surface of the display panel, a protective layer on a front surface of the display panel, and an adhesive layer between the protective layer and the display panel. The protective layer includes a substrate layer disposed on the adhesive layer and a low reflection layer disposed on the substrate layer, and a cohesive energy density of the adhesive layer is 10,000 Pa or more at 70 Celsius.

### CROSS-REFERENCE TO RELATED APPLICATIONS

This application is based on Korean Patent Application No. 10-2025-0042136 filed on Apr. 1, 2025, the entire contents of which are incorporated herein by reference.

### BACKGROUND

Some example embodiments relate to a display device and/or to an electronic device comprising the same.

A display device is or includes a device for displaying images and includes a display panel such as an organic light emitting display panel and/or a liquid crystal display panel. The display device may include a window and a protective layer for protecting the display panel from external impact.

### SUMMARY

Some example embodiments provide a display device including an adhesive layer having strong durability even at high temperatures and an electronic device comprising the same.

A display device according to some example embodiments includes a display panel, a sealing layer on a side surface of the display panel, a protective layer on a front surface of the display panel, and an adhesive layer between the protective layer and the display panel, wherein the protective layer includes a substrate layer on the adhesive layer and a low reflection layer on the substrate layer, and a cohesive energy density of the adhesive layer is 10,000 Pa or more at 70 degrees Celsius (C).

The cohesive energy density of the adhesive layer may be 13,000 Pa or more at 70 Celsius.

A loss tangent (Tano) of the adhesive layer may be 0.20 or more at 70 Celsius.

A modulus of the adhesive layer may be 2.0 MPa or more at 70 Celsius.

An adhesive force of the adhesive layer may be 100 gf/25 mm or more when the adhesive layer is peeled at a 180° angle and at a temperature of 70 Celsius.

The adhesive force of the adhesive layer may be about 1200 gf/25 mm or less when peeled at a 180° angle and a temperature of 25 Celsius.

The adhesive layer includes a solvent, a main monomer, a comonomer, a functional group-containing monomer, a crosslinking agent, and a tackifier, and a content of the functional group-containing monomer may be 5 wt % to 10 wt % based on a total content of the adhesive layer.

A content of the crosslinking agent may be 3 wt % to 5 wt % based on the total content of the adhesive layer.

A content of the tackifier may be 3 wt % to 5 wt % based on the total content of the adhesive layer.

The adhesive layer may have anisotropy in a plane perpendicular to a direction in which the front surface of the display panel faces.

The tackifier may be segregated on a surface of the adhesive layer in contact with the display panel.

A thickness of the adhesive layer may be 10 μm to 30 μm.

The adhesive layer and the protective layer may at least partially overlap the sealing layer.

The display device may further include a window disposed on the display panel, and the window and the protective layer may be bonded through the adhesive layer.

The adhesive layer may contact the window and the sealing layer.

The display device may further include a heat dissipation sheet and a bottom chassis, both disposed on a rear surface of the display panel.

An electronic device according to some example embodiments includes a display device and a processor, wherein the display device includes: a display panel, a sealing layer on a side surface of the display panel, a protective layer on a front surface of the display panel, and an adhesive layer between the protective layer and the display panel. The protective layer includes a substrate layer on the adhesive layer and a low reflection layer on the substrate layer, and a cohesive energy density of the adhesive layer is 10,000 Pa or more at 70 Celsius.

A loss tangent of the adhesive layer may be 0.20 or more at 70 Celsius.

A modulus of the adhesive layer may be 2.0 MPa or more at 70 Celsius.

An adhesive force of the adhesive layer may be 100 gf/25 mm or more when peeled at a 180° angle at 70 Celsius.

According to some example embodiments, an adhesive layer disposed between a display panel and a protective layer has strong durability and high adhesive force even at high temperatures, and thus a display device in which the protective layer does not lift from, or is less likely to lift or delaminate from, the display panel even under external impact, and/or an electronic device comprising the same can be provided.

### BRIEF DESCRIPTION OF THE DRAWINGS

FIG. 1 is an exploded perspective view of a display device according to some example embodiments.

FIG. 2 is a cross-sectional view of a display device according to some example embodiments.

FIG. 3 is a cross-sectional view showing a window, an adhesive layer, and a protective layer of a display device according to some example embodiments.

FIG. 4 is a graph showing storage modulus according to strain of a protective layer according to some example embodiments and an adhesive layer according to a comparative example.

FIG. 5 is a cross-sectional view showing a high-temperature pressurization evaluation method for a display device according to some example embodiments.

FIG. 6 is a cross-sectional view showing a high-temperature inclined vibration test method of a display device according to some example embodiments.

FIG. 7 is a diagram showing a molecular structure of an adhesive layer according to some example embodiments.

FIG. 8 is a cross-sectional view showing a window, an adhesive layer, and a protective layer of a display device according to some example embodiments.

FIG. 9 is a block diagram of an electronic device according to some example embodiments.

FIG. 10 shows schematic diagrams of electronic devices according to various embodiments.

### DETAILED DESCRIPTION

Hereinafter, various example embodiments will be described in detail with reference to the accompanying drawings so that those of ordinary skill in the art can easily implement inventive concepts. Inventive concepts may be implemented in various different forms and is not limited to the example embodiments described herein.

To clearly describe example embodiments, parts not related to the description may be omitted, and the same reference numerals are assigned to the same or similar components throughout the specification.

In addition, because the size and/or thickness of each component shown in the drawings are arbitrarily shown for convenience of description, example embodiments are not necessarily limited to what is shown. In the drawings, the thicknesses are enlarged to clearly express various layers and regions. In the drawings, for convenience of description, the thicknesses of some layers and regions are exaggerated.

In addition, in a case that a part such as a layer, layer, region, plate, and the like is said to be “on” or “above” another part, this includes not only the case where it is “directly on” another part, but also the case where there is another part in between. Conversely, in case that a part is said to be “directly on” another part, this may mean that there is no other part in between. In addition, being “on” or “above” a reference part means being disposed above or below the reference part, and does not necessarily mean being disposed “on” or “above” in the direction opposite to gravity.

In addition, throughout this description, in case that a part is said to “include” a certain component, this means that it may further include other components rather than excluding other components unless specifically stated to the contrary.

In addition, throughout this description, in case that referring to “planar view,” this means the target part is viewed from above, and in case that referring to “cross-sectional view,” this means a cross-section obtained by vertically cutting the target part is viewed from the side.

In addition, throughout this description, “about” or “approximately” may include within +30%, 20%, 10%, or 5% of the corresponding numerical range, e.g., up to a reasonable engineering tolerance or manufacturing tolerance.

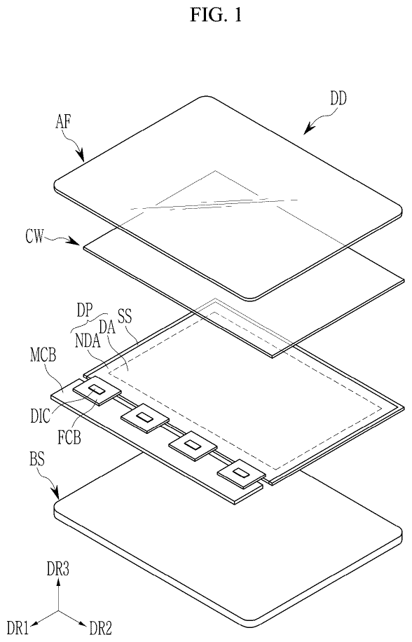

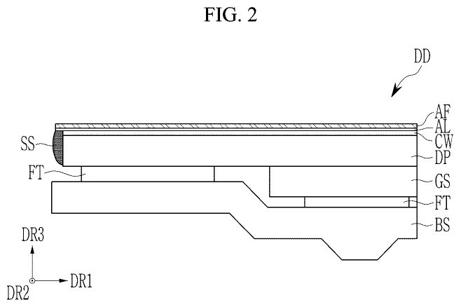

Hereinafter, a display device according to some example embodiments will be described with reference to FIGS. 1 and 2. FIG. 1 is an exploded perspective view of a display device according to some example embodiments. FIG. 2 is a cross-sectional view of a display device according to some example embodiments.

A display device DD according to some example embodiments may be or may include (or be included in) a display device included in large electronic devices such as televisions and/or monitors, as well as small and medium-sized electronic devices such as one or more of mobile phones, tablets, laptops, car navigation devices, and game machines. These are only examples, and of course, other types of electronic devices may be included as long as they do not deviate from the concept of the present disclosure. The display device DD may have a rectangular shape having a short side in a first direction DR1 and a long side in a second direction DR2 intersecting the first direction DR1. However, the shape of the display device DD is not limited thereto, and display devices DD of various shapes may be provided. An aspect ratio or a ratio of lengths of the long side to the short side may be greater than one and less than two, e.g., about 1.1, 1.2, 1.3, 1.4, 1.5, 1.6, 1.7, 1.8, or 1.9; example embodiments are not limited thereto.

The display device DD may display an image toward a third direction DR3 on a display surface parallel to each of the first direction DR1 and the second direction DR2. A display surface on which an image is displayed may correspond to a front surface of the display device DD. The image may include a dynamic image as well as a still image.

In some example embodiments, a front surface (or upper surface) and a rear surface (or lower surface) of each member are defined based on a direction in which an image is displayed. The front surface and the rear surface are opposing to each other in the third direction DR3, and a normal direction of each of the front surface and the rear surface may be parallel to the third direction DR3. A separation distance between the front surface and the rear surface in the third direction DR3 may correspond to a thickness in the third direction DR3.

The display device DD may sense external input applied from the outside. The external input may include various types of inputs provided from outside the display device DD. The display device DD according to some example embodiments may sense external input, e.g., input of a user applied from the outside. The external input of the user may be any one or more of various types of external inputs such as a part of the user's body, light, heat, gaze, or pressure, or a combination thereof. Alternatively or additionally, the display device DD may sense external input of a user applied to a side surface or rear surface of the display device DD according to the structure of the display device DD, and is not limited to any one example embodiment.

As shown in FIGS. 1 and 2, the display device DD may include a window CW, a protective layer AF, a bottom chassis BS, and a display panel DP.

A display panel DP according to some example embodiments may be, may include, or may be included in a light emitting display panel. As a representative example, the display panel DP may be or may include one or more of an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include quantum dots and quantum rods, and the like. Hereinafter, in some example embodiments, the display panel DP is described as an organic light emitting display panel.

The display panel DP outputs an image, and the output image may be displayed through a display surface. The display panel DP may include a display area DA and a non-display area NDA surrounding the display area DA. The display area DA may be or may correspond to an area where an image is displayed, and in some cases the display DA area may include pixels. A shape of the display area DA may be substantially defined by the non-display area NDA. However, this is shown as one example, and the non-display area NDA may be disposed adjacent to only one side of the display area DA or may be omitted.

A window CW disposed on the display panel DP may be made of a transparent material capable of transmitting an image. For instance, the window CW may be composed of glass, plastic, or a combination thereof.

The window CW may be bonded to the display panel DP through a pressure sensitive adhesive (PSA), an optically clear adhesive (OCA), and/or the like.

Referring to FIGS. 1 and 2, a protective layer AF may be disposed on the window CW. The protective layer AF is disposed at an upper portion of the display device DD and may protect, or at least partially protect, the display panel DP disposed at a lower portion. In addition, the protective layer AF may prevent or reduce, e.g., may reduce the amount of and/or the impact from, reflection of external light entering the display device DD. The protective layer AF may be formed of a plurality of layers or may be formed of a single layer.

Referring to FIG. 2, an adhesive layer AL may be disposed between the protective layer AF and the window CW. The protective layer AF may be bonded to the window CW through the adhesive layer AL. The adhesive layer AL may be made of or may include an optically transparent adhesive such as a pressure sensitive adhesive and/or an optically clear adhesive.

Referring to FIG. 1, the display device DD may further include a main circuit board MCB, a flexible circuit layer FCB, a data driving circuit DIC, a driving controller, and a voltage generator. The main circuit board MCB may be connected to the flexible circuit layer FCB and electrically connected to the display panel DP. The flexible circuit layer FCB is connected to the display panel DP and electrically connects the display panel DP and the main circuit board MCB. The main circuit board MCB may include a plurality of driving elements. The plurality of driving elements may include circuit units for driving the display panel DP. A data driving circuit DIC may be mounted on the flexible circuit layer FCB. The flexible circuit layer FCB may be bent so that the data driving circuit DIC is disposed on a rear surface of the display panel DP. In addition, the data driving circuit DIC may be directly mounted on the main circuit board MCB.

In some example embodiments, the driving controller and the voltage generator may be disposed on the main circuit board MCB. The driving controller and the voltage generator may be electrically connected to the display panel DP through the main circuit board MCB and the flexible circuit layer FCB.

Referring to FIGS. 1 and 2, the display device DD may further include a sealing layer SS disposed on a side surface of (e.g., on one or more side surfaces of) the display panel DP. The sealing layer SS may surround a portion of an edge of the display panel DP. The sealing layer SS may be disposed on remaining surfaces of the side surfaces of the display panel DP except for a surface on which the flexible circuit layer FCB is disposed. The sealing layer SS may seal the side surface of the display panel DP to prevent or reduce the amount of light leakage from the side of the display panel DP. The sealing layer SS may include an acrylic resin.

Referring to FIG. 2, the sealing layer SS may overlap, or at least partly overlap, the adhesive layer AL and the protective layer AF in the third direction DR3. The adhesive layer AL may contact the window CW and the sealing layer SS and cover the window CW and the sealing layer SS.

The display device DD may include a bottom chassis BS disposed on a rear surface of the display panel DP. The bottom chassis BS may accommodate the display panel DP and may define an appearance of the display device DD. The bottom chassis BS absorbs impacts applied from the outside and may prevent or reduce the amount of and/or impact from foreign substances/moisture from penetrating into the display panel DP. The bottom chassis BS may include a material having relatively high rigidity. For instance, the bottom chassis BS may include one or more of glass, plastic, or metal, or may include a plurality of frames and/or plates composed of a combination thereof.

Either or both of the protective layer AF and the bottom chassis BS may have at least one rounded and/or chamfered corner, for example, one, two, three, or four rounded and/or chamfered corners. Example embodiments are not limited thereto.

Referring to FIG. 2, the display device may further include a heat dissipation sheet GS disposed on a rear surface of the display panel DP. The heat dissipation sheet GS may include graphite. The heat dissipation sheet GS has high thermal conductivity and may dissipate or may help to dissipate heat generated in the display panel DP to the outside.

In some example embodiments, the bottom chassis BS may be bonded to the display panel DP and the heat dissipation sheet GS through a foam tape FT having adhesive force on both surfaces. The foam tape FT may be disposed at edges of the bottom chassis BS.

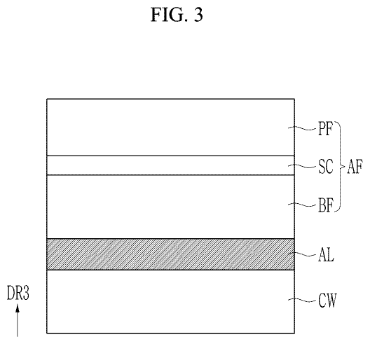

Hereinafter, a window, a protective layer, and an adhesive layer of a display device according to some example embodiments will be described with reference to FIG. 3. FIG. 3 is a cross-sectional view schematically showing a window, a protective layer, and an adhesive layer of a display device according to some example embodiments.

Referring also to FIG. 2, a window CW, an adhesive layer AL, and a protective layer AF may be disposed on the display panel DP. The window CW and the protective layer AF may be bonded through the adhesive layer AL.

The window CW may be made of a transparent material including at least one of glass and plastic.

An adhesive layer AL may be disposed on the window CW. The adhesive layer AL may be made of or may include an optically transparent adhesive such as a pressure sensitive adhesive and/or an optically clear adhesive.

A thickness of the adhesive layer AL in the third direction DR3 may be 10 μm to 50 μm, 10 μm to 30 μm, or 20 μm. However, the thickness of the adhesive layer AL is not limited thereto and may be changed in a range that maintains adhesive force and durability.

In some example embodiments, an adhesive force of the adhesive layer AL may be 100 gf/25 mm or more when peeled at an angle of 180° and a temperature (e.g., an ambient temperature) of 70 Celsius. For instance, the adhesive force of the adhesive layer AL may be 100 gf/25 mm or more when peeled from glass at a speed of 300 mm/min and at 70 Celsius. For example, the adhesive layer AL may have high adhesive force even at high temperatures of 70 Celsius or higher.

The adhesive force of the adhesive layer AL may be 1200 gf/25 mm or less in case that peeled at 180° angle at 25 Celsius. For instance, the adhesive force of the adhesive layer AL may be 1200 gf/25 mm or less when peeled from glass substrate at a speed of 300 mm/min at 25 Celsius. For example, the adhesive layer AL is not excessively sticky at room temperature and may have balanced adhesive force across different temperatures.

In some example embodiments, a modulus of the adhesive layer AL may be 2.0 MPa or more at 70 Celsius. For example, the adhesive layer AL may not be easily deformed by external impact even at high temperatures of 70 Celsius or higher and may maintain sufficient stiffness. The modulus of the adhesive layer AL may be 2.0 MPa or more, or 2.5 MPa or more at 25 Celsius. The modulus may be measured with a nanoindenter; however, example embodiments are not limited thereto.

In some example embodiments, a loss tangent (Tano) of the adhesive layer AL may be 0.20 or more at 70 Celsius. The loss tangent (Tano) may be defined as a ratio of storage modulus and loss modulus. The higher the loss tangent, the more energy the material can absorb and convert to heat. The adhesive layer AL of the display device according to some example embodiments may serve as a cushion by absorbing impact well, even in a high-temperature environment of 70 Celsius or higher. The loss tangent (Tano) may be measured with a rheometer; however, example embodiments are not limited thereto.

In some example embodiments, a surface tackiness of the adhesive layer AL may be 0.2 mN or more.

In some example embodiments, a cohesive energy density of the adhesive layer AL may be 10,000 Pa or more, or 13,000 Pa or more at 70 Celsius. The adhesive layer AL may maintain internal cohesive strength of the material even at high temperatures and may not be separated or torn or delaminated even by external impact. The cohesive energy density may be measured with a rheometer; however, example embodiments are not limited thereto. In a case where the cohesive energy density of the adhesive layer AL is 10,000 Pa or more, an incidence of delamination may be 0%. The incidence of delamination may mean or may indicate the proportion of specimens in which lifting occurs in the protective layer in a high-temperature inclined vibration test among a plurality of specimens.

The display device according to some example embodiments includes an adhesive layer AL having high adhesive strength, high durability, high-temperature stability, and high material strength, so that the entire protective layer AF remains or is more likely to remain fully adhered without lifting of an edge of the protective layer AF even under external impact at high temperatures.

For instance, during distribution of the display device or during the display device's lifetime, even if a shear direction impact perpendicular to the third direction DR3 is applied to the sealing layer SS of FIG. 2, the adhesive layer AL is not deformed so that an edge of the protective layer AF does not lift.

The adhesive layer AL may include a solvent, a main monomer, a comonomer, a functional group-containing monomer, a crosslinking agent, and a tackifier.

The solvent may include at least one selected from the group consisting of (or the group including) ethyl acetate, toluene, hexane, acetone, and isopropanol. In some example embodiments, a content of the solvent may be 40 wt % to 50 wt %, or 45 wt % based on a total content of the adhesive layer.

The main monomer may include at least one selected from the group consisting of (or the group including) ethyl acrylate, butyl acrylate, and 2-ethylhexyl acrylate. In some example embodiments, a content of the main monomer may be 30 wt % to 40 wt %, or 30 wt % based on the total content of the adhesive layer.

The comonomer may be at least one selected from the group consisting of (or the group including) vinyl acetate, acrylonitrile-butadiene-styrene, and methyl methacrylate. In some example embodiments, a content of the comonomer may be 0 to 10 wt %, or 5 wt % based on the total content of the adhesive layer.

The functional group-containing monomer may include at least one selected from the group consisting of (or the group including) acrylic acid, methacrylic acid, 2-hydroxyethyl acrylate, 2-hydroxyethyl methacrylate, dimethylaminoethyl methacrylate, and acrylamide. In some example embodiments, a content of the functional group-containing monomer may be 0 to 15 wt %, 5 wt % to 15 wt %, 5 wt % to 10 wt %, or 10 wt % based on the total content of the adhesive layer.

The crosslinker may include at least one selected from the group consisting of (or the group including) hydroxyethyl acrylate, hydroxy methacrylate, hydroxypropyl methacrylate, acrylic acid, methacrylic acid, itaconic acid, maleic anhydride, glycidyl acrylate, and glycidyl methacrylate. In some example embodiments, a content of the crosslinking agent may be 0 to 7 wt %, or 3 wt % to 7 wt %, or 5 wt % based on the total content of the adhesive layer.

The tackifier may include at least one selected from the group consisting of (or the group including) rosin ester, xylene resin, phenolic resin, and terpene resin. In an embodiment, the tackifier may be 0 to 5 wt %, or 5 wt % based on the total content of the adhesive layer.

Referring to FIG. 3, the protective layer AF may include a substrate layer BF and a low reflection layer SC. The protective layer AF is disposed at an upper portion of the display panel to protect or at least partially protect the display panel from external impact and may reduce reflection of external light entering the display device.

A substrate layer BF may be disposed on the adhesive layer AL. The substrate layer BF may include a transparent material. The substrate layer BF may include glass and/or a polymer layer. For instance, substrate layer BF may include polymer layers such as polyimide (PI), polyethylene terephthalate (PET), triacetyl cellulose (TAC), and cyclic olefin polymer (COP). The substrate layer BF may be composed of a single layer or multiple layers.

A low reflection layer SC may be disposed on the substrate layer BF. The low reflection layer SC may be or may include (or be included in), for instance, a layer having a reflectance of 1% or less. The low reflection layer SC may include zirconium oxide (ZrO₂). The low reflection layer SC may play a substantial role in reducing external light reflectance of the display device.

A total thickness of the substrate layer BF and the low reflection layer SC in the third direction DR3 may be 50 μm to 100 μm. The thicknesses of the substrate layer BF and the low reflection layer SC are not limited thereto and may be changed; for example, the thickness may be in a range that maintains mechanical strength and/or the flexibility.

The protective layer AF may further include a temporary layer PF disposed on the low reflection layer SC. The temporary layer PF may be disposed at an outermost portion of the display device to protect the display device. The temporary layer PF may be detached/detachable and/or attached/attachable by a user.

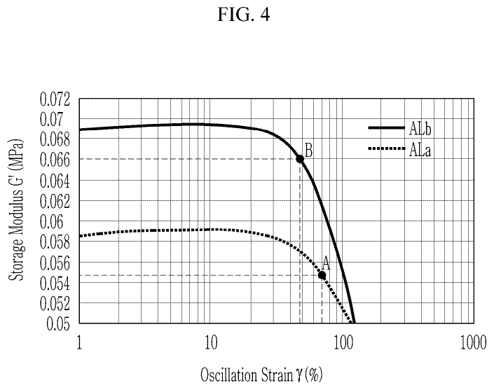

Hereinafter, a cohesive energy density of an adhesive layer of a display device according to some example embodiments will be described with reference to FIG. 4. FIG. 4 is a graph showing storage modulus according to vibration strain of an adhesive layer according to some example embodiments and an adhesive layer according to a comparative example.

FIG. 4 is a graph showing changes in storage modulus according to vibration strain when the frequency is 1 Hz at 70 Celsius.

A content of the functional group-containing monomer of the adhesive layer ALa according to some example embodiments is greater than a content of the functional group-containing monomer of the adhesive layer ALb according to a comparative example. A content of the crosslinking agent of the adhesive layer ALa according to some example embodiments is greater than a content of the crosslinking agent of the adhesive layer ALb according to a comparative example. A content of the tackifier of the adhesive layer ALa according to some example embodiments is greater than a content of the tackifier of the adhesive layer ALb according to a comparative example.

An adhesive force of the adhesive layer ALa according to some example embodiments is 100 gf/25 mm or more when peeled at a 180° angle at a speed of 300 mm/min and at 70 Celsius. An adhesive force of the adhesive layer ALb according to a comparative example is less than 100 gf/25 mm when peeled at a 180° angle at a speed of 300 mm/min at 70 Celsius.

A modulus of the adhesive layer ALa according to some example embodiments is 2.0 MPa or more at 70 Celsius, and a modulus of the adhesive layer ALb according to a comparative example is less than 2.0 MPa at 70 Celsius.

A loss tangent (Tano) of the adhesive layer ALa of the display device according to some example embodiments is 0.20 or more at 70 Celsius, and a loss tangent of the adhesive layer ALa of the display device according to a comparative example is less than 0.20 at 70 Celsius.

In FIG. 4, a linear viscoelastic region limit (LVR Limit) of the adhesive layer ALa according to some example embodiments is indicated as A, and a linear viscoelastic region limit of the adhesive layer ALb according to a comparative example is indicated as B. The linear viscoelastic region limit may be a point at which the viscoelastic response of a material begins to change non-linearly.

Referring to Table 1, at A, the vibration strain (γ_{crit}) and storage modulus (G′_{VLR}) are 70.75% and 0.0548 MPa, respectively. At B, the vibration strain (γ_{crit}) and storage modulus (G′_{VLR}) are 46.88% and 0.0662 MPa, respectively.

TABLE 1

| | A | B |
|---|---|---|
| Storage Modulus(G′_{VLR})[MPa] | 0.0548 | 0.0662 |
| Vibration Strain(γ_{crit}) [%] | 70.75 | 46.88 |
| Cohesive Energy Density(E_{coh})[MPa] | 0.0137 | 0.0073 |

The relationship among storage modulus (G′_{VLR}), critical oscillatory strain (Ycrit), and cohesive energy density (E_{coh}) at the linear viscoelastic region limit is as Equation 1.

$${E}_{coh} = \frac{1}{2} {G}_{VLR}^{′} {γ}_{crit}^{2} \qquad [ Equation 1 ]$$

At A, the cohesive energy density (E_{coh}) is 0.0137 MPa, and at B, the cohesive energy density (E_{coh}) is 0.0662 MPa.

Therefore, because the adhesive layer ALa according to some example embodiments has a higher cohesive energy density than the adhesive layer ALb according to a comparative example, the material maintains cohesive force even at high temperatures and is not easily separated or delaminated, so tearing may not occur or may be less likely to occur, even under external impact.

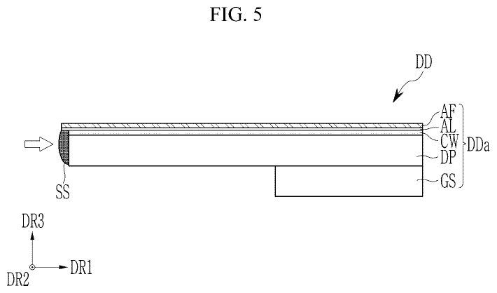

Hereinafter, a high-temperature pressurization evaluation of a display device according to some example embodiments will be described with reference to FIG. 5. FIG. 5 is a cross-sectional view showing a high-temperature pressurization evaluation method of a display device according to some example embodiments.

Referring to FIG. 5, a specimen DDa does not include the bottom chassis BS and may include the display panel DP, the window CW, the sealing layer SS, the adhesive layer AL, the protective layer AF, and the heat dissipation sheet GS.

The high-temperature pressurization evaluation may evaluate the form of the protective layer AF by heating and pressing in a shear direction perpendicular to the third direction DR3 (e.g., parallel to the horizontal plain defined by directions DR1 and DR2).

First, heating may be performed in the first direction DR1 or the second direction DR2 from the sealing layer SS side of the specimen DDa. For instance, heating may be performed at 70 Celsius for 1 minute or more.

Next, the sealing layer SS of the specimen DDa may be pressed in the first direction DR1 or the second direction DR2. For instance, pressing may proceed at 5 mm/min, and pressure may gradually increase.

Through the high-temperature pressurization evaluation, pressure at which lifting occurs at an edge of the protective layer AF may be measured. The lifting occurrence pressure may be 8.0 kgf or more, 8.5 kgf or more, or 10.0 kgf or more. This may be confirmed with the naked eye and/or by using a microscope.

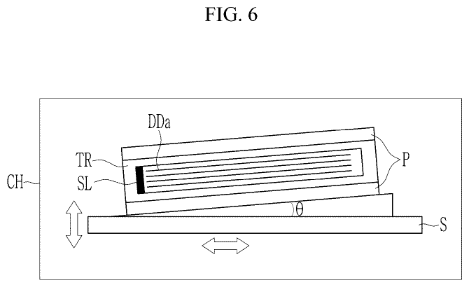

Hereinafter, a high-temperature inclined vibration test of a display device according to some example embodiments will be described with reference to FIG. 6 together with FIG. 5. FIG. 6 is a cross-sectional view showing a high-temperature inclined vibration test method of a display device according to some example embodiments.

Referring to FIG. 6, the high-temperature inclined vibration test is conducted in a high-temperature chamber CH, and a vibration test is conducted by placing a tray TR including a plurality of specimens DDa on a stage S having a certain inclination. The tray TR may be fixed by a pallet P on the stage S. The number of the plurality of specimens DDa may be 10.

For instance, the vibration test may be conducted for 60 minutes on a stage S having an inclination angle (θ) of 5° in a high-temperature chamber CH at 70 Celsius. The vibration frequency is 1 Hz, and the horizontal vibration width and vertical vibration width may be 100 mm. The horizontal vibration direction may form an inclination angle (θ) with the first direction DR1 or the second direction DR2, and the vertical vibration direction may form an inclination angle (θ) with the third direction DR3.

Referring to FIGS. 5 and 6, the plurality of specimens DDa may be stacked in the third direction DR3 in the tray TR. A slot SL for fixing the plurality of specimens DPa toward the sealing layer SS may be disposed in the tray TR. During the high-temperature inclined vibration test, the sealing layer SS and the slot SL may collide, and at this time, a shear direction impact may be applied to the sealing layer SS and the adhesive layer AL.

After completion of the high-temperature inclined vibration test, the number of specimens DDa in which lifting of an edge of the protective layer AF occurs among the plurality of specimens DDa may be confirmed. Because the cohesive energy density of the adhesive layer AL according to some example embodiments is 10,000 Pa or more, an inclined vibration lifting occurrence rate of the display device is 0%. The inclined vibration lifting occurrence rate may mean the number of specimens DDa in which lifting occurs in the protective layer AF among the plurality of specimens DDa in the high-temperature inclined vibration test.

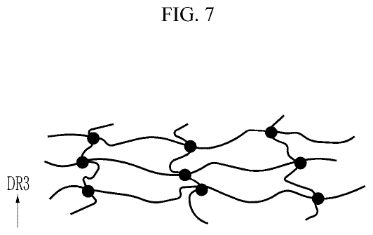

Hereinafter, a molecular structure of an adhesive layer according to some example embodiments will be described with reference to FIG. 7 together with FIG. 3. FIG. 7 is a diagram showing an internal structure of an adhesive layer according to some example embodiments.

Referring to FIG. 7, the adhesive layer AL may have a molecular structure having anisotropy, e.g., may have physical and/or chemical properties that vary depending on a direction in which they are measured. For instance, the molecular structure of the adhesive layer AL may have anisotropy on a surface perpendicular to the third direction DR3. Accordingly, stiffness of the adhesive layer AL in a shear direction may be further increased.

For instance, spacing and distribution between cross-link points may be varied according to the type of monomer of the adhesive layer AL.

Anisotropy may be generated in the adhesive layer AL by stretching the substrate layer (BF in FIG. 3), attaching the adhesive layer (AL in FIG. 3), and then shrinking again. For instance, in case that the substrate layer BF is stretched in one direction, for instance, the first direction DR1, and the adhesive layer AL is attached and then dried, the substrate layer BF shrinks and the adhesive layer AL may be stretched in a direction perpendicular to the one direction, for instance, in or along the second direction DR2.

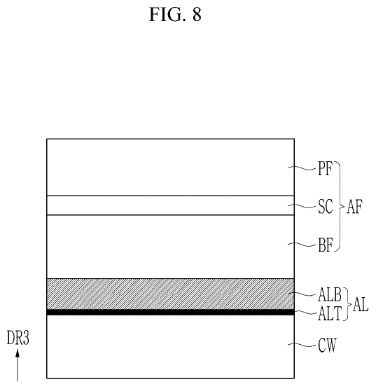

Hereinafter, a structure of an adhesive layer according to some example embodiments will be described with reference to FIG. 8. FIG. 8 is a cross-sectional view schematically showing a window, a protective layer, and an adhesive layer of a display device according to some example embodiments. Descriptions of the same components as the aforementioned components will be omitted.

Referring to FIG. 8, the adhesive layer AL may be composed of multiple layers including an adhesive substrate layer ALB and an adhesion-imparting layer ALT. The adhesion-imparting layer ALT may be disposed between the window CW and the adhesive substrate layer ALB.

An adhesion-providing layer ALT may be formed by segregating an adhesive on the surface of the adhesive layer AL. For instance, the adhesion-providing layer ALT may be formed by evaporating a solvent on the surface of the adhesive layer AL which may increase the concentration of the adhesive on the surface. In addition, a layer having a similar surface energy to the adhesive may be attached to the surface of the adhesive layer AL to segregate the adhesive to the surface. A tackifier having higher surface energy than the substrate layer BF may be used to segregate the tackifier to a surface contacting the window CW.

The adhesion-imparting layer ALT has a relatively high concentration of tackifier and may increase adhesive force between the adhesive layer AL and the window CW. The adhesive substrate layer ALB has a relatively low concentration of tackifier, so that the modulus of the adhesive layer AL may be maintained high without deterioration.

The display device according to the embodiment may be applied to various electronic devices. An electronic device according to some example embodiments includes the above-described display device and may further include modules or devices with additional functions besides the display device.

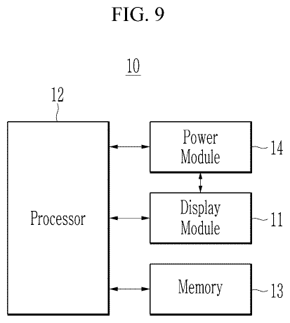

FIG. 9 is a block diagram of an electronic device according to some example embodiments. Referring to FIG. 8, an electronic device 10 according to some example embodiments may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

Data information desirable for operation of the processor 12 or the display module 11 may be stored in the memory 15. In case that the processor 12 executes an application, e.g., an application stored in the memory 15, video data signals and/or input control signals are transmitted to the display module 11, and the display module 11 may process the provided signals to output video information through a display screen. The video data signals and/or the input control signals may be transmitted in wired manner and/or in a wireless manner, in various formats such as but not limited to an analog format and/or a digital format.

The power module 14 may include a power supply module such as a power adapter and/or a battery device and a power conversion module that converts power supplied by the power supply module to generate power desirable for operation of the electronic device 10.

At least one of the respective components of the above-described electronic device 10 may be included in the display device according to the above-described embodiments. In addition, some of the individual modules functionally included in one module may be included in the display device and others may be provided separately from the display device. For instance, the display device may include the display module 11, and the processor 12, the memory 13, and the power module 14 may be provided in the form of other devices in the electronic device 10 rather than the display device.

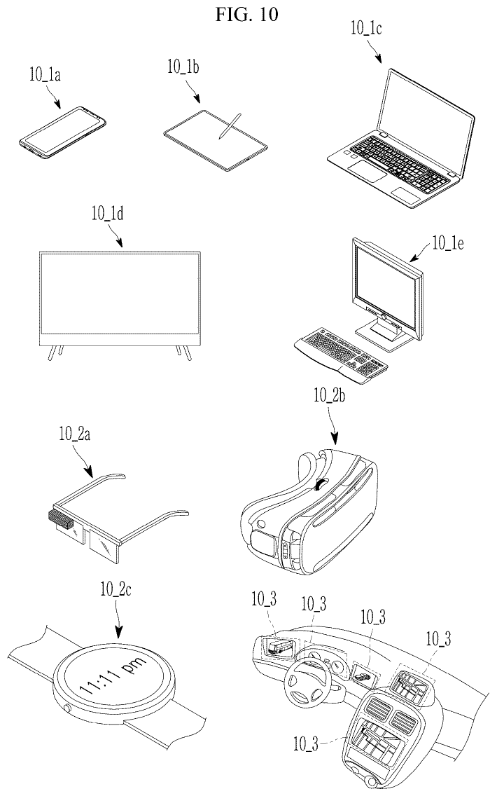

FIG. 10 shows schematic diagrams of electronic devices according to various example embodiments.

Referring to FIG. 10, various electronic devices to which the display device according to the embodiments is applied may include not only electronic devices for image display such as one or more of a smartphone 10_1a, a tablet PC 10_1b, a laptop 10_1c, a TV 10_1d, and a desktop monitor 10_1e, but also or alternatively to wearable electronic devices including a display module such as smart glasses 10_2a, a head mounted display 10_2b, and a smart watch 10_2c, and vehicle electronic devices 10_3 including a display module such as an instrument panel of a vehicle, a center fascia, a CID (Center Information Display) disposed on a dashboard, a room mirror display, and the like.

Although some example embodiments have been described in detail above, the scope of rights of inventive concepts is not limited thereto, and various modifications and improvements by those of ordinary skill in the art using example embodiments defined in the following claims also belong to the scope of rights. Furthermore, example embodiments are not necessarily mutually exclusive with one another. For example, some example embodiments may include one or more features described with reference to one or more figures, and may also include one or more other features described with reference to one or more other figures.

### DESCRIPTION OF SYMBOLS

DP: display panel
SS: sealing layer
AF: protective layer
AL: adhesive layer
BF: substrate layer
SC: low reflection layer

What is claimed is:

1. A display device comprising:
a display panel;
a sealing layer on a side surface of the display panel;
a protective layer on a front surface of the display panel; and
an adhesive layer between the protective layer and the display panel,
wherein the protective layer comprises,
a substrate layer on the adhesive layer, and
a low reflection layer on the substrate layer, and wherein
a cohesive energy density of the adhesive layer is 10,000 Pa or more at 70 Celsius.

2. The display device of claim 1, wherein the cohesive energy density of the adhesive layer is 13,000 Pa or more at 70 Celsius.

3. The display device of claim 1, wherein a loss tangent (Tano) of the adhesive layer is 0.20 or more at 70 Celsius.

4. The display device of claim 1, wherein a modulus of the adhesive layer is 2.0 MPa or more at 70 Celsius.

5. The display device of claim 1, wherein an adhesive force of the adhesive layer is 100 gf/25 mm or more when peeled at an angle of 180° and at 70 Celsius.

6. The display device of claim 5, wherein the adhesive force of the adhesive layer is 1200 gf/25 mm or less when peeled at a 180° angle and a temperature of 25 Celsius.

7. The display device of claim 1, wherein
the adhesive layer comprises a solvent, a main monomer, a comonomer, a functional group-containing monomer, a crosslinking agent, and a tackifier, and
a content of the functional group-containing monomer is 5 wt % to 10 wt % based on a total content of the adhesive layer.

8. The display device of claim 7, wherein a content of the crosslinking agent is 3 wt % to 5 wt % based on the total content of the adhesive layer.

9. The display device of claim 7, wherein a content of the tackifier is 3 wt % to 5 wt % based on the total content of the adhesive layer.

10. The display device of claim 7, wherein the adhesive layer has anisotropy in a plane perpendicular to a direction in which the front surface of the display panel faces.

11. The display device of claim 7, wherein the tackifier is segregated on a surface of the adhesive layer, the surface of the adhesive layer being in contact with the display panel.

12. The display device of claim 1, wherein a thickness of the adhesive layer is 10 μm to 30 μm.

13. The display device of claim 1, wherein the adhesive layer and the protective layer at least partially overlap the sealing layer.

14. The display device of claim 13, further comprising:
a window on the display panel, wherein the window and the protective layer are bonded through the adhesive layer.

15. The display device of claim 14, wherein the adhesive layer contacts the window and the sealing layer.

16. The display device of claim 1, further comprising:
a heat dissipation sheet and a bottom chassis, both disposed on a rear surface of the display panel.

17. An electronic device comprising:
a display device; and
a processor,
wherein the display device comprises,
a display panel,
a sealing layer on a side surface of the display panel,
a protective layer on a front surface of the display panel, and
an adhesive layer between the protective layer and the display panel,
wherein the protective layer comprises,
a substrate layer disposed on the adhesive layer; and
a low reflection layer disposed on the substrate layer, wherein
a cohesive energy density of the adhesive layer is 10,000 Pa or more at 70 Celsius.

18. The electronic device of claim 17, wherein a loss tangent of the adhesive layer is 0.20 or more at 70 Celsius.

19. The electronic device of claim 17, wherein a modulus of the adhesive layer is 2.0 MPa or more at 70 Celsius.

20. The electronic device of claim 17, wherein an adhesive force of the adhesive layer is 100 gf/25 mm or more when peeled at an angle of 180° and at 70 Celsius.
